(19) United States
(12) Patent Application Publication
(10) Pub. No.: US 2008/0191348 A1
(43) Pub. Date: Aug. 14, 2008

(54) SYSTEM FOR DISTRIBUTING ELECTRICAL POWER FOR A CHIP

(75) Inventors: Georg Meyer-Berg, Muenchen (DE); Thomas Moehring, Muenchen (DE)

Correspondence Address: LEE & HAYES, PLLC, 421 W RIVERSIDE, SUITE 500, SPOKANE, WA, 99201, US

(73) Assignee: Infineon Technologies AG, Munchen (DE)

(21) Appl. No.: 11/674,958

(22) Filed: Feb. 14, 2007

(51) Int. Cl. H01L 23/48

(52) U.S. Cl. 257/738; 257/773; 257/E23.01

(57) ABSTRACT

A system for distributing electrical power for a chip comprises a plurality of electrically conductive linear trunks arranged in a metallization layer of a chip, wherein the trunks are slanted with respect to the side edges of the chip. A further system for distributing electrical power for a chip comprises a plurality of electrically conductive straps, each one of the straps comprising two trunks connected to each other at a connection point, and a plurality of electrically conductive bumps or pads connected to the straps.

### BACKGROUND OF THE INVENTION

The present invention relates to a system for distributing electrical power for a chip.

In recent years modern high performance integrated circuit (IC) chips have been developed which require large numbers of interconnections between the upper level IC structure, or die, and the lower IC structure, or package. Prior methods for providing these interconnections include wire-bonding, wherein the die is mounted to the package or substrate with connections between the top surface of the die and the surface of the package. The die and the package are then mounted to the motherboard. Another known method for providing connections is through tape automated bonding (TAB) or Wafer Level Ball grid array (WLB) technologies.

A further method used to join the die to the package is the so-called “flip-chip” packaging process. The flip-chip process utilizes a monolithic semiconductor unit having bead-like solder bump terminals provided on one surface of the chip. These bumps are densely packed together on the die surface, thereby facilitating electrical connections to the substrate. The proximity of the solder bumps on the die to the associated terminals on the package have the benefit of decreasing the overall resistance in transmitting power or signals between the package and the die, improving overall system performance. Similar restrictions are valid for ICs packaged in WLBs and following remarks for flip-chip are valid for WLBs as well. The main difference is that, for flip-chip the pads carry the bumps, but at ICs in a WLB, the pads are left open for being contacted directly by a redistribution layer.

The problem with flip-chip designs is providing an efficient arrangement and orientation of the bumps. Flip-chip designs require the signal and pad supply bumps to be placed closed to the boundary of the chip, to satisfy electrical as well as routability requirements. Typically, one will find three or more outermost rows of bumps occupied by signals and pad supply. As a consequence, the bumps for the core supply (power and ground) are restricted to the center area of the core. Core supply current has to be transported from the center towards the chip boundary, and into the corners, where one will usually find the highest “IR” or voltage drops. (The voltage drops are termed “IR” drops based on Ohm's law which equates voltage (V) with current (I) multiplied by resistance (R), thus, V is equivalent to IR). A robust mesh with at least one horizontal and one vertical routing layer is required to meet the IR drop requirements. This robust mesh occupies remarkable routing resources, leading to either increased chip size or an additional routing layer.

Among the metallization layers of the chip, the aluminum layer (LB or AlPad) can be used for core power distribution with horizontal or vertical strapping. However, this strapping is limited to the center area of the core, where the core supply bumps are located. In the boundary area, where the signal and pad supply bumps are placed, the aluminum layer is usually occupied by the redistribution routing, i.e., the connections from the bumps to the pad cells. So, the aluminum layer supports the core power distribution only in the core center area. At the core boundary and in the corners, however, lower routing layers are required extensively for power distribution.

### BRIEF DESCRIPTION OF THE SEVERAL VIEWS OF THE DRAWINGS

In the following, specific embodiments of the invention will be explained in more detail in the following text with reference to the accompanying drawings, in which:

FIG. 1 shows a schematic representation of an embodiment of a system for distributing electrical power for a chip;

FIG. 2 shows a schematic representation of a further embodiment of a system for distributing electrical power for a chip;

FIG. 3 shows a schematic representation of a further embodiment of a system for distributing electrical power for a chip.

### DETAILED DESCRIPTION OF THE INVENTION

The aspects and embodiments of the invention are now described with reference to the drawings, wherein like reference numerals are generally utilized to refer to like elements throughout. In the following description, for purposes of explanation, numerous specific details are set forth in order to provide a thorough understand of one or more aspects of embodiments of the invention. It may be evident, however, to one skilled in the art that one or more aspects of the embodiments of the invention may be practiced with a lesser degree of the specific details. In other instances, known structures and devices are shown in a schematic form in order to facilitate describing one or more aspects of the embodiments of the invention. The following description is therefore not to be taken in a limiting sense, and the scope of the invention is defined by the appended claims.

In the following description embodiments of a system will be outlined which is designed in order to distribute electrical power for a chip. The chip can be any kind of chip and is not limited to any specific kind of chip. In particular, the chip can be any kind of semiconductor chip such as, for example, an integrated circuit (IC) chip, a power transistor chip, a logic circuit chip or a memory chip.

In addition, according to an embodiment of a system for distributing electrical power for a chip, it is described that linear electrically conductive trunks are arranged in a metallization layer of a chip. It is to be noted that the electrically conductive trunks can be any kind of electrically conductive wires, rails or any other sort of elongated electrically conductive connection paths.

Furthermore, according to a further embodiment of a system for distributing electrical power for a chip, electrically conductive straps are described wherein each one of the electrically conductive straps comprise two trunks connected to each other at a connection point. It is to be noted that the electrically conductive trunks can be any kind of electrically conductive wires, rails or any other sort of electrically conductive elongated connection paths.

Also, according to a further embodiment of a system for distributing electrical power for a chip, there are described electrically conductive bumps connected to the straps. It is to be noted that the electrically conductive bumps can be any kind of electrically conductive bumps, beads, balls or any other electrically conductive elevations.

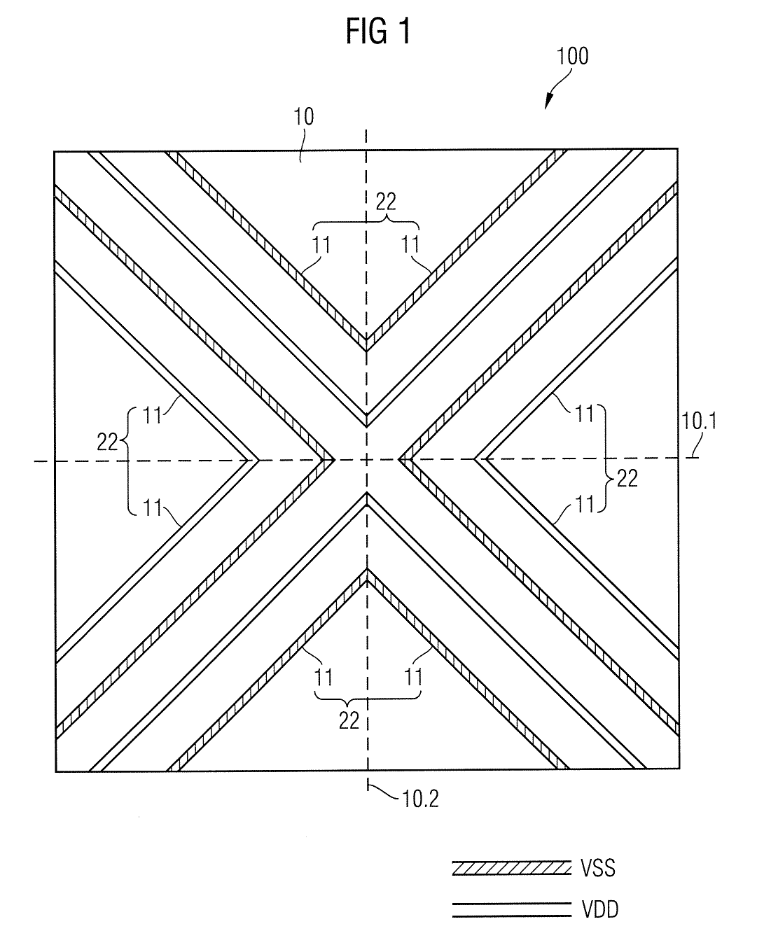

Referring to FIG. 1, there is shown a schematic representation of an embodiment of a system for distributing electrical power for a chip. There is shown in FIG. 1 a view of a chip 100 from above one of the chip's main surfaces. The chip 100 comprises a metallization layer 10. The system for distributing electrical power for the chip 100 comprises a plurality of electrically conductive linear trunks 11 which are arranged within the metallization layer 10 of the chip 100. The trunks 11 are slanted with respect to the side edges 12 of the chip 100.

As shown in the embodiment of FIG. 1, it can be the case that pairs of trunks 11 are formed wherein each pair two trunks 11 are connected together. Each pair of trunks 11 is connected to one of a supply potential or a ground potential. The supply potential and the ground potential may correspond to the voltages VDD and VSS which are known as standard voltage levels supplied to a chip. The supply potential and the ground potential may be supplied from external sources in various ways, one of which will be described in a further embodiment described below. Inside the chip 100 the supply potential and the ground potential may be distributed via connections between the trunks 11 and other metallization layers of the chip 100.

As shown in the embodiment of FIG. 1, the trunks 11 may be arranged such that each of them is oriented at a 45° angle with respect to one of the side edges 12 of the chip 100. It can also be the case that the trunks are oriented with a degree in a range of 40° to 50° with respect to one of the side edges 12 of the chip 100. Moreover, in the embodiment as shown in FIG. 1 the chip 100 has the shape of a square. However, it can also be the case that the chip has the general form of a rectangle and that the trunks are oriented along the diagonal lines of the rectangle.

As further shown in FIG. 1, there may be defined a horizontal center line 10.1 and a vertical center line 10.2 wherein both center lines 10.1 and 10.2 pass through a center of the metallization layer 10. The trunks 11 may then be arranged in such a way that each of them comprises one end lying on one of the center lines 10.1 or 10.2. The trunks 11 can be further arranged in such a way that they have one end lying near one of the side edges of the chip 100.

As shown in the embodiment of FIG. 1, the trunks 11 can be connected together in pairs thereby forming V-shaped straps 22. The tip of the V-shaped straps, i.e. the connection point of the interconnected trunks 11, can lie on one of the center lines 10.1 or 10.2. The V-shaped straps 22 can be arranged such that they comprise one or both of an axial symmetry and a rotational symmetry. As shown in the embodiment of FIG. 1, the V-shaped straps comprise an axial symmetry in that their configuration is symmetric with respect to the horizontal center line 10.1 and also with respect to the vertical center line 10.2. The configuration of the V-shaped straps comprises also a rotational symmetry. In particular, the configuration of the V-shaped straps comprises a four-fold rotational symmetry which means that the configuration is reproduced by a rotation about 360°/4°=90°. In the present embodiment as depicted in FIG. 1 there is formed a first set of V-shaped straps 22 which is comprised of trunks having a 45° and 135° orientation, respectively, a second set of V-shaped straps 22 comprised of trunks 11 having a 135° and 225° orientation, respectively, a third set of V-shaped straps 22 comprised of trunks 11 having a 225° and 315° orientation, respectively, and a fourth set of V-shaped straps 22 comprised of trunks 11 having a 315° and 45° orientation, respectively. The angle values are taken with respect to the vertical center line 10.2 which is indicated in the top portion of FIG. 1.

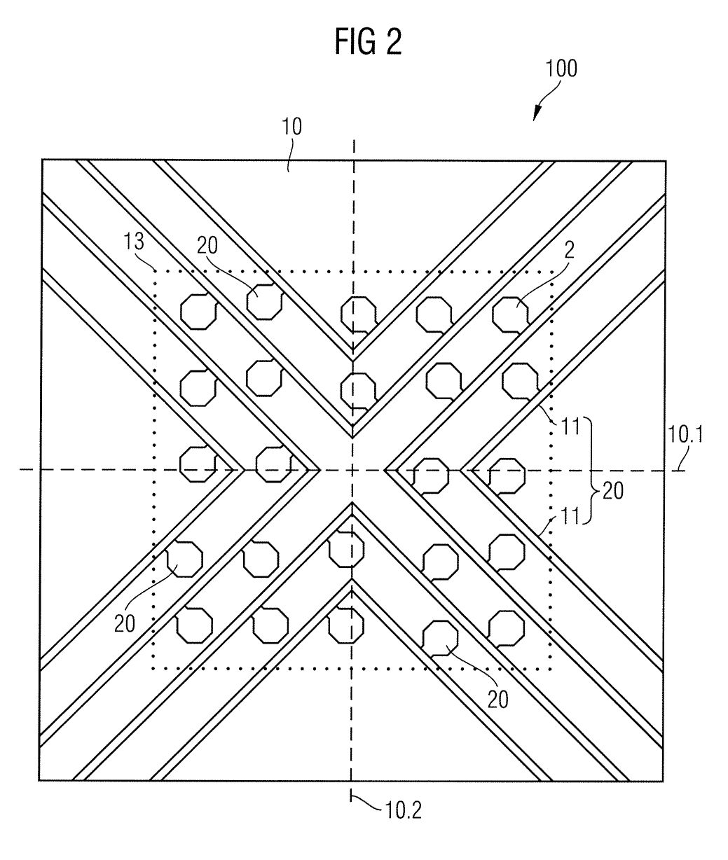

Referring to FIG. 2 there is shown a schematic representation of a further embodiment of a system for distributing electrical power for a chip. In addition to the embodiment as depicted in FIG. 1, the embodiment according to FIG. 2 shows a plurality of electrically conductive bumps 20 which are connected to the straps 22. The bumps 20 are connected with the straps 22 as shown in the figure. The configuration may be such that the metallization layer 10 presenting the straps 22 is covered by an insulation or passivation layer (not shown). The bumps 20 are then deposited onto the insulation or passivation layer and connections are formed through the insulation or passivation layer allowing the bumps 20 to be connected with the straps 22. The chip 100 is mounted in a flip-chip configuration to a printed circuit board (PCB) by soldering the bumps 20 to contact pads on the PCB.

The bumps 20 may be arranged above a center area or core area 13 of the chip 100. The boundary of the center area 13 is indicated by the dotted line in FIG. 2. Within this center area 13 the bumps 20 may be arranged in a matrix form. Due to the arrangement of the straps, no bump is provided in the center of the matrix.

From the center area 13 in which the bumps 20 are placed, the electrical power is distributed toward the edges 12 and the corners 14 of the chip 100. The straps 22 can be made from aluminum in an aluminum metallization layer of the chip. When using the 45/135/225/315 degree strapping, the IR drop critical areas will move from the corners 14 of the chip 100 to the middle of each edge 12 of the chip 100. The distance to the well-supplied core center 13 is significantly reduced. The IR drop target can thus be met with much fewer resources on the lower routing layers. Additionally, some horizontal (left and right hand side) and vertical (bottom and top side) straps can be added, if required.

The straps 22 or trunks 11 do not need to have constant width. It can be provided that the diameter of each one of the trunks 11 decreases with decreasing distance from the edge 12 of the chip 100, i.e. from one of the side edges 12 of the chip 100. Near the edges 12 the trunks can get thinner in order to allow narrower pitch of straps 22 and bumps 20.

The configuration of one or both of the straps 22 and bumps 20 can comprise one or both of an axial symmetry or a rotational symmetry. In FIG. 2 there is depicted an embodiment showing both axial symmetry and rotational symmetry. The configuration of the straps 22 comprises an axial symmetry in that it is symmetric with respect to both the horizontal center line 10.1 and to the vertical center line 10.2. The straps 22 themselves and also the whole configuration of straps 22 and bumps 20 comprises a rotational symmetry wherein not only the straps 22 comprise a rotational symmetry as explained in connection with the embodiment of FIG. 1, but also the arrangement of the bumps 20 in the embodiment of FIG. 2 is such that the whole configuration comprises a rotational symmetry. In the present embodiment the whole configuration comprises a four-fold symmetry which means that the configuration is reproduced by a rotation about 360°/4°=90°.

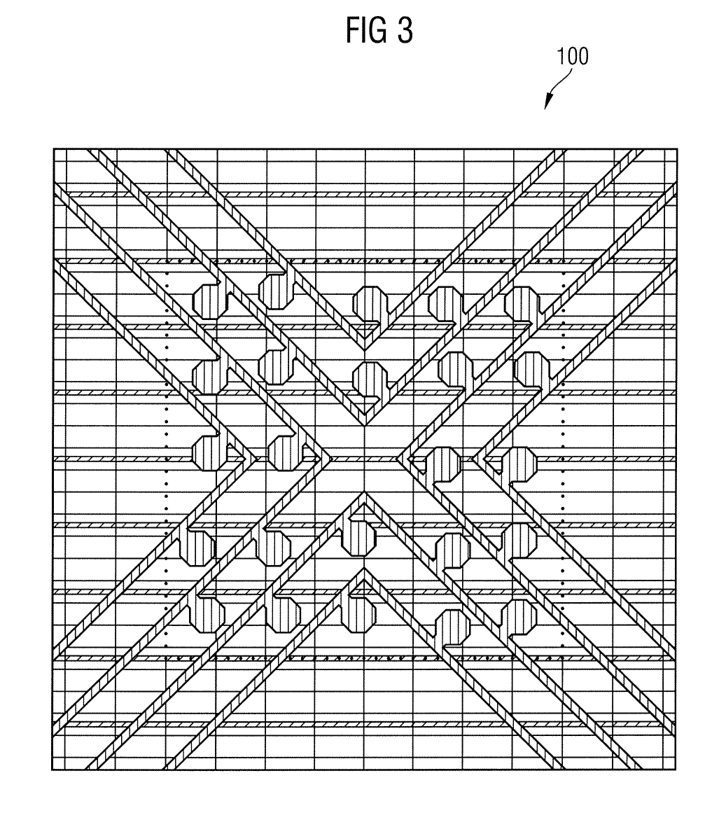

Referring to FIG. 3 there is shown a schematic representation of a further embodiment of a system for distributing electrical power for a chip 100. In addition to the embodiment as depicted in FIG. 2, the embodiment of FIG. 3 also shows the power meshes of the lower metallization layers of the chip. There is shown a chip according to the design configuration C11 4M-MQ-LB. The horizontal thin lines correspond to the standard cell VDD/VSS rails in the metallization layer M1. The vertical thick lines correspond to the VDD/VSS straps in the metallization layer M4. The horizontal thick lines correspond to the VDD/VSS straps in the metallization layer MQ (M5). The density of the mesh in the metallization layers M4 and MQ (M5) is much less than that required in prior art solutions.

For distributing the electrical power from the bumps 20 and the straps 22 to the next lower metallization layer (M5) there may be provided connections (not shown) between the straps 22 and the electrical lines of the mesh of the M5 layer.

What is claimed is:

1. A system for distributing electrical power for a chip, comprising:
a plurality of electrically conductive linear trunks arranged in a metallization layer of a chip, wherein the trunks are slanted with respect to side edges of the chip.

2. The system according to claim 1, wherein
the chip comprises the shape of a rectangle, and the trunks are oriented along diagonal lines of the rectangle.

3. The system according to claim 1, wherein
the chip comprises the shape of a square, and the trunks are oriented with a degree in a range of 40° to 50°, in particular 45°, with respect to one of the side edges of the chip.

4. The system according to claim 1, wherein
the trunks are oriented either parallel or perpendicular to each other.

5. The system according to claim 1, further comprising:
a vertical center line and a horizontal center line, wherein both center lines pass through a center of the metallization layer, and wherein
each one of the trunks has one end lying on one of the center lines.

6. The system according to claim 5, wherein
each one of trunks has one end lying at one of the side edges of the chip.

7. The system according to claim 1, wherein
pairs of trunks are formed wherein each pair two trunks are connected together.

8. The system according to claim 5, wherein
the connection point of the two trunks lies on one of the vertical center line and the horizontal center line.

9. The system according to claim 7, wherein
each one of the pairs of trunks is connected to a supply potential or a ground potential.

10. The system according to claim 1, wherein
an arrangement of the trunks includes one or both of an axial symmetry or a rotational symmetry.

11. The system according to claim 10, wherein
the arrangement of the trunks comprises a four-fold rotational symmetry.

12. The system according to claim 1, further comprising:
a plurality of bumps or pads connected to the trunks.

13. The system according to claim 12, wherein
the bumps or pads are arranged within a center area of the chip.

14. The system according to claim 12, wherein
the bumps or pads are arranged in a matrix form.

15. The system according to claim 12, further comprising:
an insulation layer deposited on the metallization layer, wherein the bumps or pads are arranged on the insulation layer; and
the insulation layer includes connections for connecting the bumps or pads with the trunks.

16. The system according to claim 1, wherein
the diameter of each one of the trunks decreases with decreasing distance from one of the side edges of the chip.

17. A system for distributing electrical power for a chip, comprising:
a plurality of electrically conductive straps, each one of the straps comprising two trunks connected to each other at a connection point; and
a plurality of electrically conductive bumps or pads connected to the straps.

18. The system according to claim 17, further comprising:
a vertical center line and a horizontal center line, wherein both center lines pass through a center of a metallization layer, in which the straps are arranged, and wherein
each one of the straps is arranged such that the connection point is located on one of the vertical center line and the horizontal center line.

19. The system according to claim 17, wherein
each one of the trunks has one end lying near one of the side edges of the chip.

20. The system according to claim 17, wherein
each one of the straps is connected to a supply potential or a ground potential.

21. The system according to claim 17, wherein
the bumps or pads are arranged within a center area of the chip.

22. The system according to claim 17, wherein
the bumps or pads are arranged in a matrix form.

23. The system according to claim 17, further comprising:
a metallization layer, in which the straps are arranged;
an insulation layer deposited on the metallization layer, wherein the bumps or pads are arranged on the insulation layer; and
the insulation layer includes connections for connecting the bumps or pads with the straps.

24. The system according to claim 17, wherein the arrangement of the straps includes one or both of an axial symmetry or a rotational symmetry.

25. The system according to claim 24, wherein
the arrangement of the straps comprises a four-fold rotational symmetry.

26. The system according to claim 17, wherein
the diameter of each one of the trunks decreases with decreasing distance from one of the side edges of the chip.
